(19) United States
(12) Patent Application Publication
(10) Pub. No.: US 2008/0283973 A1
(43) Pub. Date: Nov. 20, 2008

(54) INTEGRATED CIRCUIT INCLUDING A DIELECTRIC LAYER AND METHOD

(75) Inventors: Lars Oberbeck, Dresden (DE); Jonas Sundqvist, Dresden (DE); Lothar Frey, Hoechstadt (DE); Alejandro Avellan, Muenchen (DE); Stefan Kudelka, Radebeul (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/104,814

(22) Filed: Apr. 17, 2008

(30) Foreign Application Priority Data
Apr. 17, 2007 (DE) 10 2007 018 013-8

(51) Int. Cl. H01L 23/58; H01L 21/469; H05K 3/00

(52) U.S. Cl. 257/632; 438/778; 427/96.1; 257/E21.487

(57) ABSTRACT

An integrated circuit including a dielectric layer and a method for producing an integrated circuit. In one embodiment, a dielectric layer is deposited in a process atmosphere. The process atmosphere includes a first starting component at a first point in time, a second starting component at a second point in time and a third starting component at a third point in time. The third starting component includes a halogen.

### CROSS-REFERENCE TO RELATED APPLICATIONS

This Utility Patent Application claims priority to German Patent Application No. DE 10 2007 018 013.8-45 filed on Apr. 17, 2007, which is incorporated herein by reference.

### BACKGROUND

The invention relates to an integrated circuit including a dielectric layer. The invention furthermore relates to a method for producing an integrated circuit including a dielectric layer.

Dielectric layers or dielectric elements are widely employed in electrical engineering. The dielectric layers, in conjunction with electrodes, are often used as capacitors or control electrodes. A capacitor may, for example, be embodied by two electrodes with a dielectric layer arranged in between, wherein the capacitance of the capacitor arises depending on the area of the electrodes, the distance between the electrodes and the dielectric constant of the dielectric layer. If the dielectric layer has a high dielectric constant, then the capacitance can be increased even with a small or limited electrode area.

It is hardly possible to imagine modern integrated circuits without dielectric layers, capacitances, control electrodes and related units. By way of example, capacitors are used as charge stores in electronic memory devices, such as in a dynamic random access memory for example. Furthermore, dielectric layers are likewise widely employed as part of a control electrode of a transistor, for example in the form of a gate electrode. A high and optimized dielectric constant of the dielectric layer is often desirable in this case.

The advancing miniaturization of the feature sizes of large scale integrated circuits has the effect that the available electrode areas and distances, and also the possible layer thicknesses, become smaller and smaller. In order to obtain a sufficiently high capacitance with small areas, therefore, the dielectric constant is often chosen to be as high as possible. Thus, high-k materials, which have a high dielectric constant, are employed for example in modern DRAM memory devices. Examples of high-k materials of this type are hafnium- or zirconium-containing oxides, transition metal oxides or barium strontium titanate.

The miniaturization of the feature sizes leads not only to a reduction of the available electrode sizes but also to a minimization of layer thicknesses. Although thin layers can permit an increase in the capacitance, disadvantageous effects can arise, such as the increase in leakage currents for example. A leakage current can disadvantageously short-circuit two electrodes via the dielectric material arranged in between, such that, by way of example, stored charge flows away in a disadvantageous manner.

Industrial and scientific methods for producing dielectric layers include sophisticated and readily reproducible methods such as, for example, layer depositions (atomic layer deposition, ALD), vapor deposition methods (physical vapor deposition—PVD, chemical vapor deposition—CVD) and other related methods.

These methods produce amorphous, crystalline, partly crystalline or polycrystalline layers having one or a plurality of interfaces with adjacent layers or between respectively two adjacent crystallites of the dielectric layer. In the context of interfaces between two crystallites of a polycrystalline material, they are also referred to as grain boundaries. At these interfaces, unsaturated bonds can lead to interface states which can lead to charge accumulation, on the one hand, and to charge transport, on the other hand. The charge accumulation and/or charge transport may be disadvantageous with regard to the dielectric constant and/or the leakage currents.

Conventional methods for producing modern dielectric layers therefore include a step of saturating the unsaturated bonds, for example by using an implantation of specific elements. However, implantation methods can considerably disrupt the structure of the irradiated materials and/or require thermal annealing, such that the implanted atoms diffuse to the interfaces in order to saturate the unsaturated bonds there. The disruption of the internal structure and/or the thermal after-treatment may be disadvantageous in the case of modern integrated circuits. Thus, by way of example, the production of modern integrated circuits is provided with only a limited thermal budget, and exceeding the latter can disadvantageously affect electronic units that have already been patterned.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A to 1C illustrate schematic views of different applications of an integrated circuit including a dielectric layer in accordance with one or more embodiments.

FIG. 2A illustrates a schematic illustration of a transistor with a dielectric layer in accordance with one embodiment.

FIG. 2B illustrates a schematic illustration of a trench capacitor with a dielectric layer in accordance with one embodiment.

FIG. 2C illustrates a schematic illustration of a stacked capacitor with a dielectric layer in accordance with one embodiment.

FIG. 2D illustrates a schematic illustration of a stack capacitor with a dielectric layer in accordance with one embodiment.

FIG. 3A to 3F illustrate schematic illustrations of a dielectric layer in accordance with a first, second, third, fourth, fifth and sixth embodiment.

FIGS. 4A to 4E illustrate schematic flowcharts of methods for producing an integrated circuit including a dielectric layer in accordance with a seventh, eighth, ninth, tenth and eleventh embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One or more embodiments provide an integrated circuit and method for producing an integrated circuit including a dielectric layer.

One embodiment provides a method for producing a dielectric layer on a substrate. The dielectric layer is deposited in a process atmosphere, wherein the process atmosphere includes a first starting component at a first point in time, a second starting component at a second point in time and a third starting component at a third point in time. The third starting component includes a halogen.

Another embodiment provides a dielectric layer on a substrate. The dielectric layer includes a first component, a second component and a third component. The third component includes a halogen.

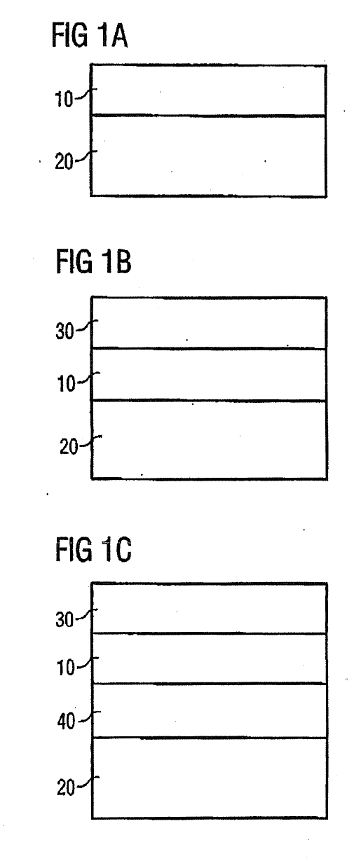

FIGS. 1A, 1B and 1C illustrate three applications of an integrated circuit including a dielectric layer in accordance with one or more embodiments. FIG. 1A illustrates a dielectric layer 10 on a substrate 20 as a basic configuration. FIG. 1B illustrates an electrode 30 in addition to the dielectric layer 10 and the substrate 20. The electrode 30 adjoins the dielectric layer 10 at a first side, while the substrate 20 adjoins the dielectric layer 10 at an opposite side. The substrate 20 can have a counterelectrode with respect to the electrode 30, for example, in the form of a doped region. FIG. 1C illustrates a further use of the dielectric layer 10 in conjunction with the substrate 20, the electrode 30 and a further electrode 40. In this case, the dielectric layer 10 is arranged between the electrode 30 and the further electrode 40. This configuration is, for example, typical of a capacitor, e.g., an MIS or MIM capacitor, arranged on the substrate 20.

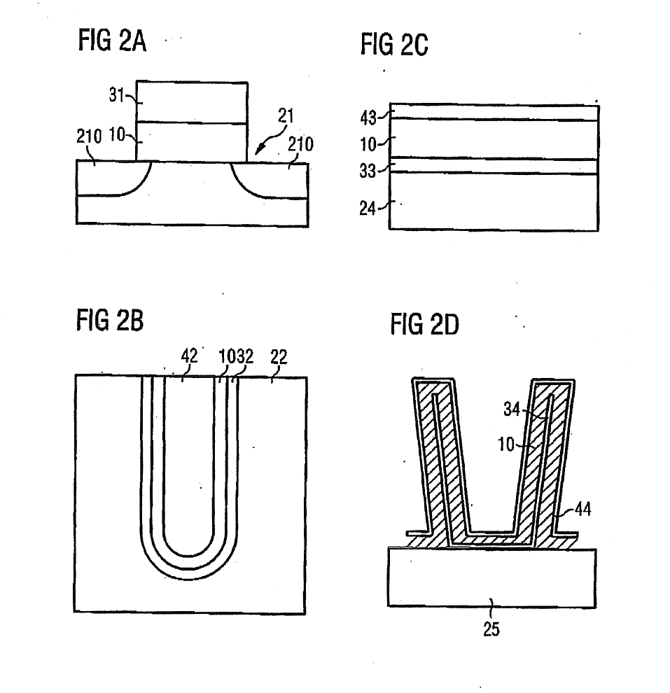

FIG. 2A illustrates an application of the dielectric layer of one embodiment in a transistor. In this case, the dielectric layer 10 is arranged on a substrate 21, for example, a silicon substrate. The substrate 21 has doped regions 210, for example, a source region and a drain region. A gate electrode 31 is arranged on the dielectric layer 10 and can control the transistor channel that forms between the two regions 210. In accordance with one embodiment, the dielectric layer 10 has a third component, which provides an optimization of the dielectric constant of the dielectric layer 10 and at the same time an effective reduction of the leakage currents. A high dielectric constant of the dielectric layer 10 enables a sufficiently good control of the transistor channel, and a reduction or suppression of leakage currents reduces or prevents a crosstalk between the source region, the drain region and/or the transistor channel with the gate electrode 31.

FIG. 2B illustrates an application of the dielectric layer 10 of one embodiment in a trench capacitor. In this case, a trench is arranged in a substrate 22, for example, in a silicon substrate. A first electrode 32 is arranged at the trench walls, which electrode can be formed as a separate conductive layer or as a correspondingly doped region of the substrate 22. The dielectric layer 10 adjoins the first electrode 32. The interior of the trench is filled, at least partly, with a second electrode 42. The arrangement of first electrode 32—dielectric layer 10—second electrode 42 constitutes a customary capacitor such as is used e.g., in DRAM memory devices. The dielectric layer 10 has a third component, which includes a halogen. Leakage currents are thereby effectively reduced or suppressed. In the use as a capacitor, charges would flow away between the electrodes 32 and 42 as a result of excessively high leakage currents. The capacitor therefore loses its charge state more rapidly and the performance of a memory device is disadvantageously impaired. An effective reduction or suppression of leakage currents is advantageous precisely in the case of miniaturized capacitors in the use as storage element since a defined charge state of the capacitor is retained for a longer period of time.

The method is suitable for the deposition of the dielectric layer 10 with a curved topography, too, since the starting components in the process atmosphere cover the substrate surface, independently of the topography. Thus, the dielectric of a capacitor, for example of the trench capacitor in FIG. 2B, can also be produced by using the method.

FIG. 2C illustrates an application of the dielectric layer 10 of one embodiment in a stacked capacitor, such as e.g., in a planar capacitor. In this case, a capacitor is arranged on a substrate 24, for example, on a silicon substrate. The capacitor includes a first electrode 33, the dielectric layer 10 and a second electrode 43. The first electrode 33 can be formed as a separate conductive layer or as a correspondingly doped region of the substrate 24. The dielectric layer 10 adjoins the first electrode 33. The arrangement of first electrode 33—dielectric layer 10—second electrode 43 constitutes a customary capacitor such as is used e.g., in DRAM memory devices. The dielectric layer 10 has a third component, which includes a halogen. Leakage currents are thereby effectively reduced or suppressed. In the use as a capacitor, charges would flow away between the electrodes 33 and 43 as a result of excessively high leakage currents.

FIG. 2D illustrates an application of the dielectric layer 10 of one embodiment in what is known e.g., as a stack capacitor. In this case, a stack capacitor is arranged on a substrate 25, for example, on a silicon substrate. The stack capacitor includes a first electrode 34, the dielectric layer 10 and a second electrode 44. The substrate 25 can in this case have a contact for making contact with the first electrode 34. The dielectric layer 10 adjoins the first electrode 34. The arrangement of first electrode 34—dielectric layer 10—second electrode 44 constitutes a customary capacitor such as is used e.g., in DRAM memory devices as cylinder type or cup type. The free space illustrated in FIG. 2D can furthermore be at least partly filled by oxides, such as e.g., silicon dioxide, or plate materials, such as e.g., tungsten. The dielectric layer 10 has a third component, which includes a halogen. Leakage currents are thereby effectively reduced or suppressed. In the use as a capacitor, charges would flow away between the electrodes 34 and 44 as a result of excessively high leakage currents.

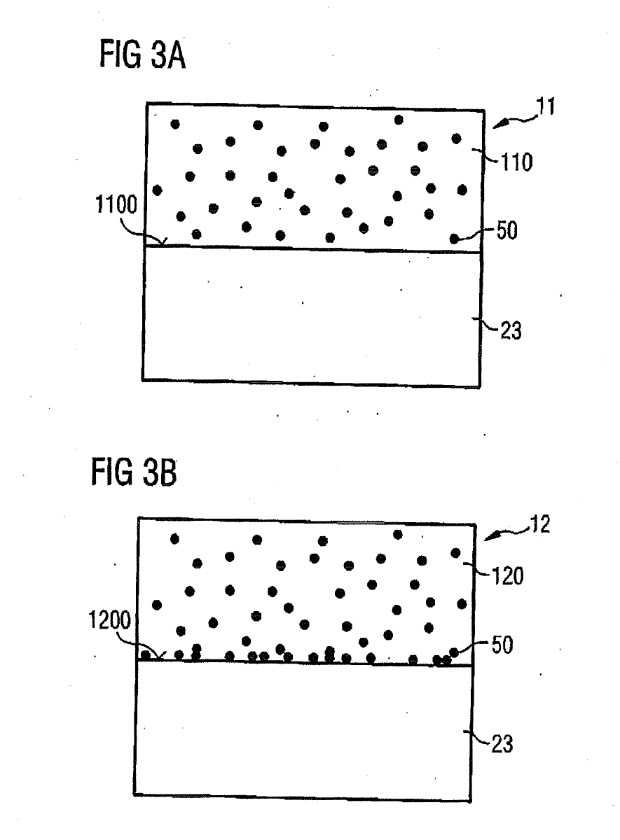

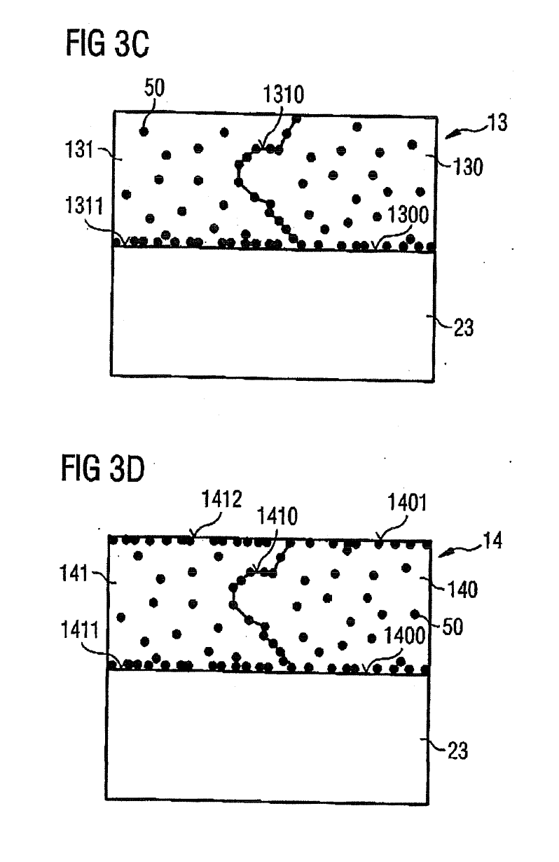

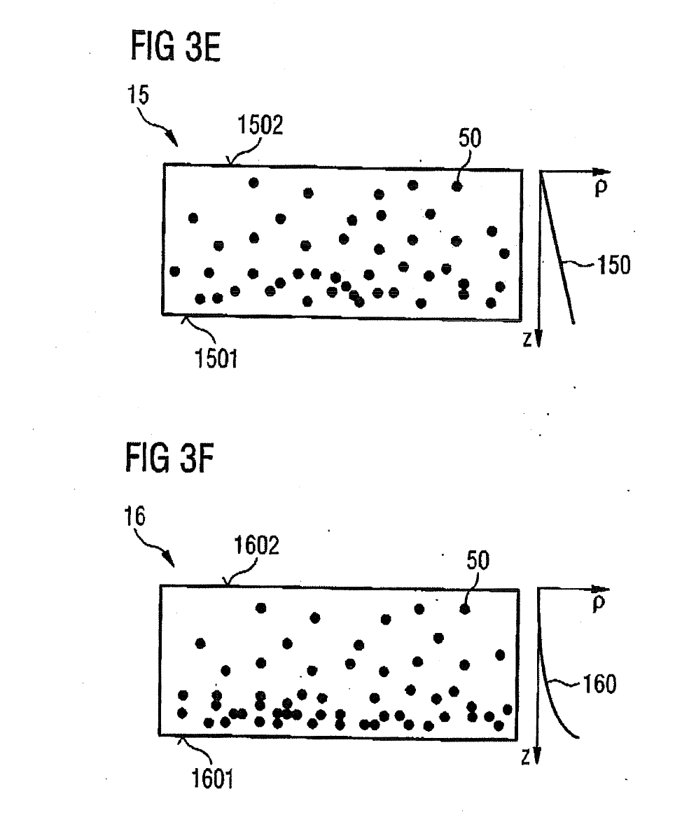

FIG. 3A illustrates a schematic illustration of a dielectric layer in accordance with one embodiment. In this case, a dielectric layer 11 is arranged on a substrate 23. An interface 1100 delimits a volume region 110 of the dielectric layer 11 from the substrate 23. The dielectric layer has a third component 50, which has a halogen. Furthermore, the dielectric layer 11 can have a first and/or second component. The first component can have one of the following substances: hafnium, barium, strontium, titanium, silicon, zirconium, lead, tantalum, aluminum and/or a metal. The second component can have oxygen and/or nitrogen. In general, the third component 50 can include a halogen, for example, fluorine, chlorine, bromine, or iodine. Furthermore, the third component 50 can be represented by individual atoms of a halogen. An example material system of the dielectric layer 11 can therefore be hafnium oxide with fluorine atoms.

In accordance with one embodiment, the volume region 110 of the dielectric layer 11 has the third component 50. The distribution of the third component 50 in the volume region 110 can be embodied homogeneously, or else inhomogeneously. A homogeneous distribution of the third component 50 shall be characterized by the fact that when the volume region 110 is divided into two partial volume regions of identical size, the number of third components 50 in a first partial region does not deviate more than 10% from the number of third component 50 in a second partial region. The volume region 110 can have less than 20%, less than 10% or less than 5% of the third component 50.

FIG. 3B illustrates a schematic view of a dielectric layer in accordance with one embodiment. A dielectric layer 12 is arranged on the substrate 23. An interface 1200 delimits a volume region 120 of the dielectric layer 12 from the substrate 23. The dielectric layer 12 has the third component 50. With regard to the additional components, substances or materials used and their distribution, reference should be made to the description of FIG. 3A.

In accordance with one embodiment, the dielectric layer 12 has the third component 50 in the volume region 120 and at the interface 1200. The third component 50 can therefore saturate unsaturated states which may be arranged primarily along the interface 1200. An accumulation of charge at the interface 1200 and/or a leakage current through the dielectric layer 12, or along the interface 1200, can thus be effectively reduced or suppressed. The unsaturated bonds arranged at the interface 1200 may be represented by free orbitals of the first or second component or of a component of the substrate 23.

FIG. 3C illustrates a schematic illustration of a dielectric layer in accordance with one embodiment. A dielectric layer 13 is arranged on the substrate 23. An interface 1300 of a volume region 130 of the dielectric layer 13 delimits the volume region 130 from the substrate 23. An interface 1310 of a further volume region 131 delimits the further volume region 131 from the volume region 130. A further interface 1311 of the further volume region 131 delimits the further volume region 131 from the substrate 23. The dielectric layer 13 furthermore has the third component 50. The interfaces 1300 and 1311, which can have the third component 50 for the passivation of unsaturated bonds, can be interfaces between a silicon substrate and a high-k dielectric layer.

In accordance with one embodiment, the dielectric layer 13 has at least two volume regions, the volume region 130 and the further volume region 131. The volumes regions 130, 131 may be represented, for example, by crystallites of a polycrystalline dielectric layer 13. The interface 1310 is to be identified as a grain boundary in this case. In accordance with one embodiment, the dielectric layer 13 has the third component 50 both in the volume regions 130, 131 and at the interfaces 1300, 1311 with the substrate 23 and at the interface 1310 between the volume regions 130, 131. In accordance with one embodiment, unsaturated states at the interfaces 1310, 1300 and 1311 are saturated or passivated by the third component 50. In addition to the reduction or suppression of charge accumulation, it is also possible to form a significant reduction or suppression of a leakage current, primarily along the interface 1310. Precisely leakage currents along an interface which reaches from one side of the dielectric layer 13 to the other side of the dielectric layer 13 in the direction of an electrode normal, such as the interface 1310, for example, can have a disadvantageous effect since a current can arise between two opposite electrodes, respectively arranged at the two sides, and charge can flow away. The provision of the third component 50 in the volume regions 130, 131 and at the interfaces 1300, 1311, 1310 reduces or suppresses the formation of leakage currents. With regard to the components, substances or materials used and their distribution, reference should be made to the description of FIG. 3A.

FIG. 3D illustrates a schematic illustration of a dielectric layer in accordance with one embodiment. A dielectric layer 14 is arranged on the substrate 23. A first interface 1400 of a volume region 140 of the dielectric layer 14 delimits the volume region 140 from the substrate 23. A first interface 1410 of a further volume region 141 delimits the further volume region 141 from the volume region 140. A second interface 1411 of the further volume region 141 delimits the further volume region 141 from the substrate 23. Furthermore, a second interface 1401 of the volume region 140 and a third interface 1412 of the further volume region delimit the volume regions of the dielectric layer 14 from further units, such as, for example, from an electrode arranged on the dielectric layer 14. The dielectric layer 14 furthermore has the third component 50.

In accordance with one embodiment, the dielectric layer 14 has at least two volume regions, the volume region 140 and the further volume region 141. The volume regions 140, 141 may be represented, for example, by crystallites of a polycrystalline dielectric layer 14. The interface 1410 is to be identified as a grain boundary in this case. In accordance with one embodiment, the dielectric layer 14 has the third component 50 both in the volume regions 140, 141 and at the interfaces 1400, 1401, 1410, 1411 and 1412 with the substrate 23, between the volume regions 140, 141 and with respect to further units. In accordance with one embodiment, unsaturated states at the interfaces 1400, 1401, 1410, 1411 and 1412 are saturated or passivated by the third component 50. With regard to advantages and properties of the components, substances or materials used and to their distribution, reference should be made to the description of FIG. 3A.

The concentrations of the third component 50 at the interfaces 1400 and 1411 with the substrate 23 or a possible electrode and the concentrations of the third component 50 at the interfaces 1401 and 1412 with a possible further electrode can be different, coordinated with one another or coordinated with the respective adjacent element, substrate or electrode or further electrode. The electrode and the further electrode may represent a bottom electrode and a top electrode.

FIG. 3E illustrates a dielectric layer in accordance with one embodiment. Accordingly, a dielectric layer 15 has the third component 50. The dielectric layer 15 has a first interface 1501 and a second interface 1502. Substrates or electrodes can be arranged in a manner adjoining the interfaces 1501, 1502. An interface normal Z shall be arranged perpendicular to the interfaces 1501, 1502. In accordance with one embodiment, a concentration of the third component 50 ρ varies along the normal Z. A linear profile 150 of the concentration ρ along the normal Z is illustrated here. Within the meaning of one embodiment, the term “linear” can relate to the actual concentration, the desired concentration or an average concentration. In applications in large scale integrated circuits, the feature sizes, thus also the lateral and vertical extent of the dielectric layer 15, can be very small, that is to say fall within the range below one μm, below 100 nm, or below 10 nm. In the case of a very small dielectric layer, a strictly linear desired concentration value 150 can no longer be realized since the number of the third component 50 does not represent a continuous quantity, and includes only a few third components 50 primarily in the atomic range. However, the intention here is to encompass in the dielectric layer 15 an actual concentration profile which corresponds to a linear profile 150 for the idealized continuous case. With regard to the advantages and properties of the components, substances or materials used and their distribution, reference should be made to the description of FIG. 3A.

FIG. 3F illustrates a dielectric layer in accordance with one embodiment. Accordingly, a dielectric layer 16 has the third component 50. The dielectric layer 16 has a first interface 1601 and a second interface 1602. Substrates or electrodes can be arranged in a manner adjoining the interfaces 1601, 1602. An interface normal Z shall be arranged perpendicular to the interfaces 1601, 1602. In accordance with one embodiment, a concentration of the third component 50 ρ varies along the normal Z. A nonlinear profile 160 of the concentration ρ along the normal Z is illustrated here. A nonlinear profile can also include a profile having at least one maximum and/or one minimum. In this case, the dielectric layer 16 has at least one partial layer parallel to one of the interfaces 1601, 1602 which has an increased concentration of the third component 50. Further examples of layers having an increased concentration are the interfaces 1601, 1602 towards substrates or electrodes themselves or a medial layer. Moreover, the concentration of the third component can turn out to be significantly lower or else be negligibly low or disappear. This can also be the interfaces 1601 and/or 1602 themselves. With regard to the term nonlinear, reference is made to the description of FIG. 3E. With regard to the advantages and properties of the components, substances or materials used and their distribution, reference should be made to the description of FIG. 3A.

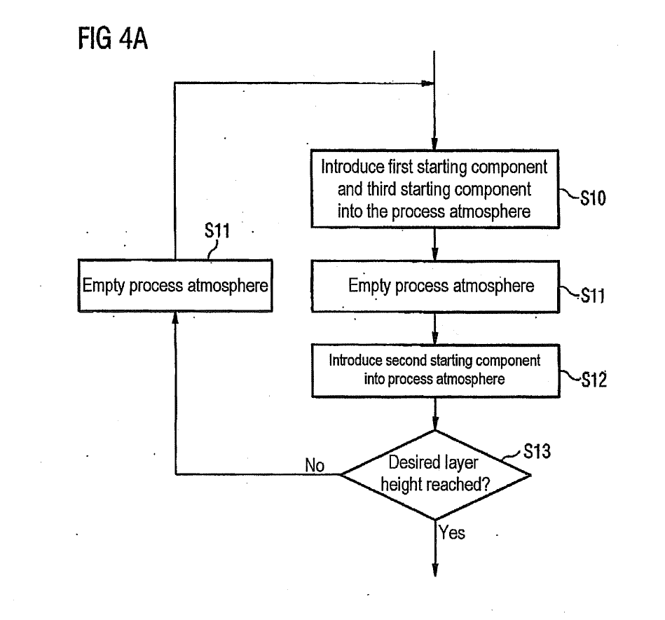

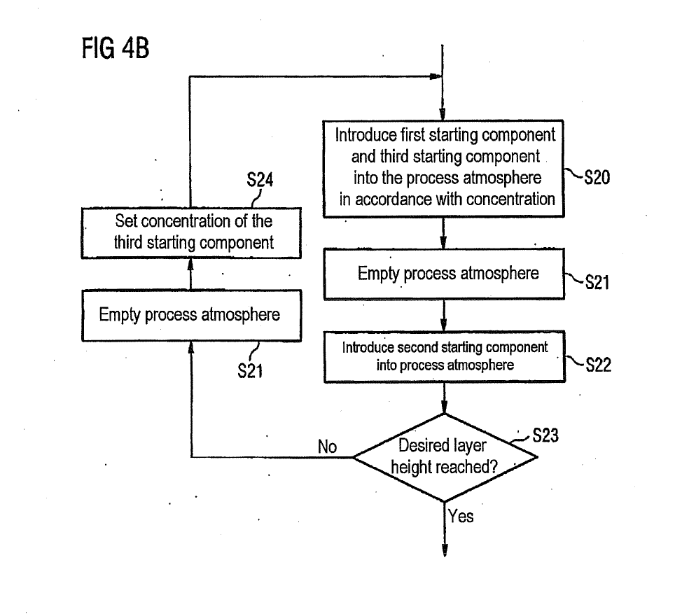

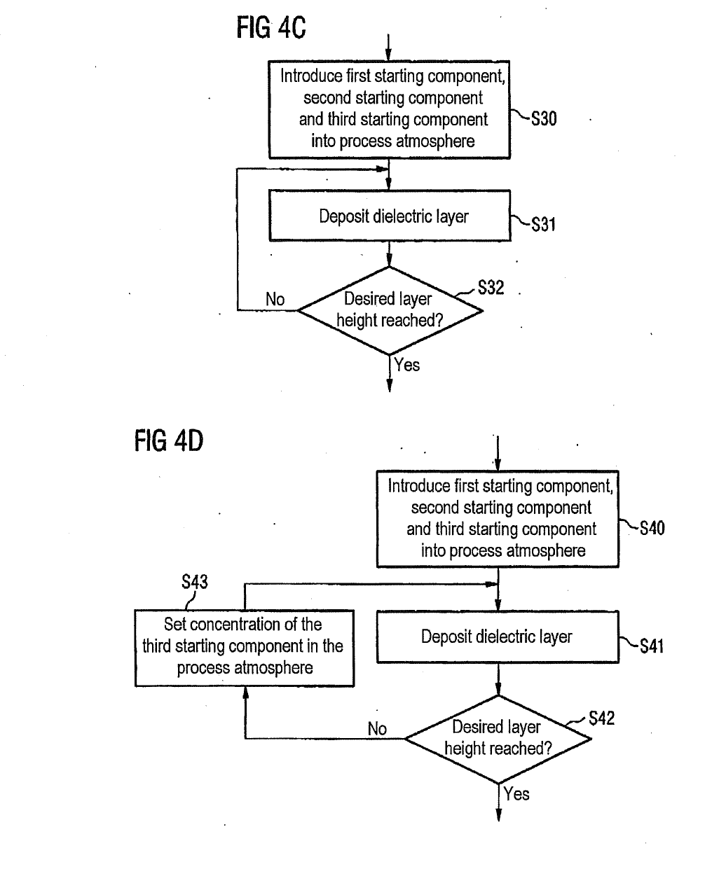

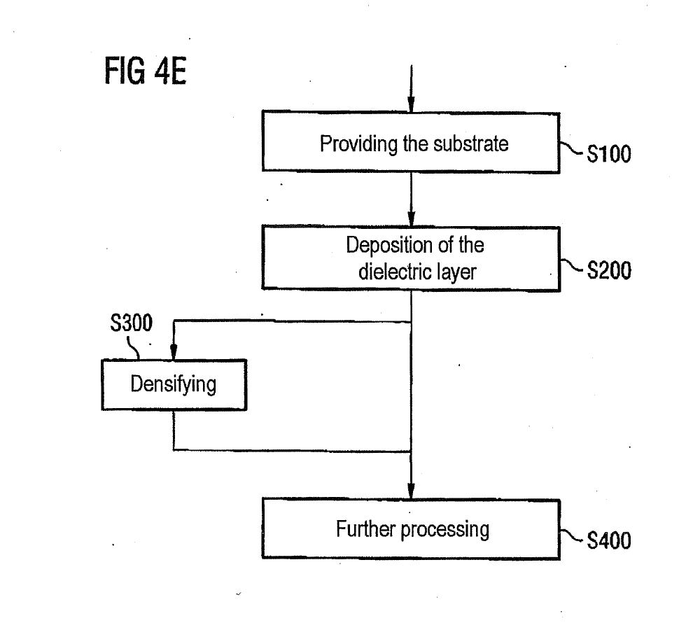

FIG. 4A illustrates a method for producing a dielectric layer in accordance with one embodiment. In a first introduction S10, a first starting component and a third starting component are introduced into a process atmosphere. The first starting component and the third starting component are thus deposited layer by layer on a substrate. The process atmosphere may have been emptied beforehand. An emptying S11 of the process atmosphere can be effected by the process atmosphere being pumped to a vacuum, for example, to a pressure of less than 10⁻² mbar, or be purged with a purge gas, for example, an inert gas such as helium, neon, argon, krypton, xenon, or nitrogen.

In general, the first component and the third component can also be provided by a starting component. In this case, the starting component then includes the first component and the third component. Examples thereof are the metal-halogen compounds that are also presented below.

The process atmosphere is thereupon emptied S11. In a second introduction S12, the second starting component is then introduced into the process atmosphere. The second starting component can react with the first starting component and/or the third starting component on the substrate in order to deposit the dielectric layer in layer by layer fashion. Possible reaction products can be removed from the process atmosphere, for example by purging with a purge gas, during an emptying S11 or else during the introduction S10, S12. In a bifurcation S13, a decision is made as to whether a desired layer height of the dielectric layer has been reached. If the desired layer height has not yet been reached, the process atmosphere is once again emptied. This is followed by a new sequence S10, S11, S12 for depositing a further partial layer of the dielectric layer. If the desired layer height has been reached, the deposition is ended and further method steps can ensue, also in situ.

Examples of layer by layer deposition methods are atomic layer deposition, nano layer deposition, atomic layer epitaxy, atomic layer chemical vapor deposition, pseudo ALD, i-ALD, plasma enhanced ALD, plasma activated ALD, metal organic ALD, thermally activated ALD, rapid ALD or sequential flow deposition. What is common to all the layer by layer deposition methods mentioned above is that the process atmosphere does not simultaneously contain all the starting components that form the layer to be deposited.

Thus, by way of example, a first starting component can have hafnium, barium, strontium, titanium, silicon, zirconium, lead, tantalum, aluminum and/or a metal. A second starting component can have oxygen and/or nitrogen. In general, a third starting component can include a halogen, for example fluorine, chlorine, bromine, or iodine.

Examples of the third starting component in accordance with the present invention include gases or vapors of liquid or solid halogens or pseudo-halogens, F₂, Cl₂, Br₂, I₂, ClF, ClF₃, ClF₅, BrF, BrF₃, BrF₅, BrCl, IF₃, IF₅, IF₇, ICl, ICL₃, IBr, HF, LiF, NaF, KBr, HBr, LiBr, NaBr, KBr, HCl, LiCl, NaCl, KCl, HI, LiI, NaI, KI, metal halides, Ti(F, Cl, Br, I)_{2.4}, Zr(F, Cl, Br, I)_{2.4}, Hf(F, Cl, Br, I)_{2.4}, Nb(F, Cl, Br, I)_{2.5}, Ta(F, Cl, Br, I)_{2.5}, lanthanide metal halides, Sc(F, Cl, Br, I)₃, Y(F, Cl, Br, I)₃, La(F, Cl, Br, I)_{2.3}, silicon halides, germanium halides, SiF₄, SiCl₄, SiBr₄, SiI₄, GeF₂, GeCl₂, GeBr₂, GeI₂, GeF₄, GeCl₄, GeBr₄, GeI₄, fluoro-, chloro-, bromo- or iodo-silanes, halogenated methyl-silanes, gases or vapors of liquid or solid halogenated organometallic compounds, halogenated silicon alkylamides, halogenated metal alkylamides, halogenated cyclopentadienyls, halogenated metal cyclopentadienyls, halogenated metallocenes, ZPDRIZPDR2MR3(F, Cl, Br, I), ZPDRIZPDR2M(F, Cl, Br, I)₂, where R denote hydrogen, a hydrocarbon group, a methyl group, an ethyl group, an alkoxy group, a methoxy group, an ethoxy group or an amide group, halogenated alkylamidinates, halogenated metal alkylamidinates, halogenated alkoxides, halogenated metal alkoxides. Furthermore, the abovementioned examples can be diluted, be present as precursors, be plasma activated, or be free radicals thereof. In general, plasma enhancement or plasma activation can be effected remote from the actual deposition location of the substrate (remote plasma). In this case, halogen atoms and/or halogen ions can be provided as third starting component.

During S11, the first starting component and the additional starting component are present in the process atmosphere. The respective precursors can react with the precursors of the second starting component in order for example to deposit a fluorine-containing hafnium oxide layer.

FIG. 4B illustrates a method for producing a dielectric layer in accordance with one embodiment. In a first introduction S20, the first starting component and the third starting component are introduced into a process atmosphere, wherein the third starting component is introduced in accordance with a predetermined concentration. The process atmosphere may have been emptied beforehand. If the process atmosphere has been emptied, the concentration of the third starting component can be set by correspondingly adapting a flow and/or an introduction time. A concentration of the third starting component in relation to the first starting component can lie within a range below 50%, below 10% or below 2%. The first starting component and the third starting component are thus deposited layer by layer on a substrate. An emptying S21 of the process atmosphere can then be effected by the process atmosphere being pumped to a vacuum, for example to a pressure of less than 10⁻² mbar, or be purged with a purge gas, for example an inert gas such as helium, neon, argon, krypton, xenon, or nitrogen.

In a second introduction S22, the second starting component is then introduced into the process atmosphere. The second starting component can react with the first starting component and/or the third starting component on the substrate in order to deposit the dielectric layer in layer by layer fashion. Possible reaction products can be removed from the process atmosphere, for example by purging with a purge gas, during an emptying S21 or else during the introduction S20, S22.

In a bifurcation S23, a decision is made as to whether a desired layer height of the dielectric layer has been reached. If the desired layer height has not yet been reached, the process atmosphere is once again empty. The concentration of the additional component is set in a setting S24. During the different iterations, the concentration in the setting S24 can be effected in a manner corresponding to a linear concentration profile, a nonlinear concentration profile and/or a concentration profile having one or more maxima. This is followed by a new sequence S20, S21, S22 for depositing a further partial layer of the dielectric layer. If the desired layer height has been reached, the deposition is ended and further method steps can ensue, also in situ.

FIG. 4C illustrates a method for producing a dielectric layer in accordance with one embodiment. In one embodiment, the first starting component, the second starting component and the third starting component are introduced into a process atmosphere. The dielectric layer is deposited in a deposition step S31 until the desired layer height has been reached. This decision can be taken continuously or at intervals.

FIG. 4D illustrates a method for producing a dielectric layer in accordance with one embodiment. In one embodiment, the first starting component, the second starting component and the third starting component are introduced into a process atmosphere. The dielectric layer is deposited in a deposition S41 until the desired layer height has been reached. This decision can be taken continuously or at intervals. During the different iterations or during the deposition S41, the concentration of the third starting component in the process atmosphere in the setting S24 can be effected in a manner corresponding to a linear concentration profile, a nonlinear concentration profile and/or a concentration profile having one or more maxima. The concentration of the third starting component can be set by adapting a flow and/or an introduction time. A concentration of the third starting component in relation to the first starting component can lie within a range below 50%, below 10% or below 2%. The first starting component and the third starting component are thus deposited layer by layer on a substrate.

One characteristic of the method in accordance with one or more embodiments is that the first starting component, the second starting component and the third starting component are introduced simultaneously in the process atmosphere. The starting components can react in order to deposit the dielectric layer on a substrate. The precursors having the first component, the second component and the third component react and leave these in the deposited dielectric layer having first, second and third components. Process products having the first starting component, the second starting component and the third starting component with respect to the first component, the second component and the third component are removed from the process atmosphere progressively or continuously. This can be done by emptying the process atmosphere, pumping the process atmosphere or purging the process atmosphere. Examples of deposition methods in accordance with one embodiment are metal organic chemical vapor deposition, chemical vapor deposition, atomic vapor deposition, plasma enhanced chemical vapor deposition, plasma activated chemical vapor deposition, or pulsed chemical vapor deposition.

The methods can include conversion into a gaseous state of the third starting component proceeding from a liquid or solid state. A conversion of this type can also be effected for the first and second starting components. Generally, substantially the concentration of the third starting component in the process atmosphere during the deposition determines the concentration of the third component in the deposited layer. A further determining factor for the concentration of the third component in the deposited layer may also be given by a ratio to the concentration of the first and/or second starting component. Furthermore, in addition to a first starting component, at least one further first starting component can be provided in order, for example, to combine two different metals with a second component. The third starting component can be coordinated with this, i.e. be present, for example, only together with the first starting component or only together with the further first starting component in the process atmosphere, in order to deposit a partial layer of the dielectric layer.

FIG. 4E illustrates a method for producing a dielectric layer in accordance with one embodiment. The method in accordance with this embodiment can include a method in accordance with one of the embodiments described above. In S100, a substrate is provided. This S100 can include parts of a CMOS process in order for example to produce an integrated circuit. The substrate can already include electronic and/or optical functional units at this stage. This includes, for example, doped regions and/or patterned trenches or interconnects in or on a semiconductor substrate.

In a deposition S200, a dielectric layer is deposited on the substrate. With regard to the methods, reference is made to the methods described in connection with FIGS. 4A to 4D.

Optionally, a densifying S300 can be effected prior to a further processing S400, which can include parts of a CMOS process. The densifying S300 increases the density of the dielectric layer and can include activation and/or diffusion of the additional component in the dielectric layer. The densifying can be effected by heating. Diffusion can furthermore be effected in connection with a thermal annealing which can also serve for activating possible electronic units in the substrate.

In general, a dielectric layer is provided on a substrate. The dielectric layer is deposited in a process atmosphere, wherein the process atmosphere includes a first starting component at a first point in time, a second starting component at a second point in time and a third starting component at a third point in time. The third starting component includes a halogen.

Accordingly, the third starting component including a halogen is incorporated into the dielectric layer during the deposition of the dielectric layer. A subsequent implantation or diffusion, under certain circumstances at elevated temperatures, is thereby avoided and the thermal loading on the component is restricted to a minimum. This not only significantly increases the process economy, but also leads to a more reliable and increased yield of the production process.

It may be provided that the additional component includes at least one of the elements of the halogens fluorine, chlorine, bromine or iodine.

The layer can be deposited by a layer by layer deposition method. Such a layer by layer deposition method is atomic layer deposition or atomic layer epitaxy, for example. In this case, the dielectric layer is deposited layer by layer, wherein the process atmosphere has the first starting component and the third starting component at the first point in time. A first partial layer having at least parts of the first starting component, for example, the first component, and parts of the third starting component, for example, the second component, is therefore formed on the substrate.

The process atmosphere can thereupon be emptied, for example, by pumping out to a minimum vacuum or by purging with a purge gas. The purge gas can also have the third starting component in order thus to incorporate the third component into the dielectric layer. In this case, it is optional for the third starting component to be present together with the first and/or second starting component in the process atmosphere. The purging with a purge gas having the third starting component can also be effected selectively only for or between specific deposition cycles. Furthermore, the third component can also be incorporated into a metal electrode, for example, into metals, metal oxides, metal nitrides or related materials.

The second starting component can then be admitted into the emptied process atmosphere. However, it is also possible for the first starting component and the third starting component to be replaced by the second starting component, for example, by purging the process atmosphere with the second starting component. A next partial layer having at least parts of the second starting component, for example, the second component, is thus formed. Parts of the first partial layer, for example, the first and/or third starting component, may react with the second starting component in order to progressively deposit the dielectric layer in this way. Process products can be discharged from the process atmosphere continuously or at intervals by purging or pumping out. A substrate temperature of the substrate during the deposition of the dielectric layer can preferably be between 150° C. and 500° C.

The dielectric layer may be deposited by using a vapor deposition method. Known vapor deposition methods are for example chemical vapor deposition, physical vapor deposition, and the numerous variants thereof. In accordance with this embodiment, the process atmosphere can have the first starting component, the second starting component and the third starting component at the first point in time. These three starting components may react in order to deposit the dielectric layer on the substrate. Process products can be discharged from the process atmosphere continuously or at intervals by purging or pumping out. A substrate temperature of the substrate during the deposition can in this case be between 0° C. and 700° C., or else correspond to a room temperature of approximately 20° C.

It may be provided that the first starting component has at least one of the following substances: hafnium, barium, strontium, titanium, silicon, zirconium, lead, tantalum, aluminum and/or a metal. The second starting component can have oxygen and/or nitrogen. One example may include a combination of a first starting component having hafnium, a second starting component having oxygen, and a third starting component having fluorine.

The process atmosphere can have the first starting component at a fourth point in time, wherein the third starting component is substantially absent in the process atmosphere at the fourth point in time. The fact that the third starting component is substantially absent in the process atmosphere means that, for example, only a residual quantity of the third starting component is contained in the process atmosphere. The process atmosphere can be emptied beforehand by being pumped, for example. Furthermore, the process atmosphere can be emptied by purging the process atmosphere by using a purge gas. The previously contained starting components are thereby substantially removed from the process atmosphere, such that the concentration of a starting component contained as a residual quantity is less than 5%, less than 1% or less than 0.1%.

The process atmosphere can have the third starting component in a first concentration at the third point in time and the process atmosphere has the third starting component in a second concentration at the fifth point in time. By this means, during the deposition of the dielectric layer, it is possible to vary the concentration of the third starting component in the process atmosphere and thus the concentration of the third component in the deposited layer. It is thus possible to realize a well-defined profile of the concentration of the third component in the dielectric layer.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for producing an integrated circuit, comprising:
providing a substrate;
depositing a dielectric layer on the substrate in a process atmosphere,
wherein the process atmosphere comprises a first starting component at a first point in time, a second starting component at a second point in time and a third starting component at a third point in time; and
wherein the third starting component comprises a halogen.

2. The method of claim 1, wherein the third starting component comprises at least one of the elements of the halogens fluorine, chlorine, bromine or iodine.

3. The method of claim 1, comprising:
depositing the dielectric layer using a layer by layer deposition method; and
wherein the process atmosphere has the first starting component and the third starting component at the first point in time.

4. The method of claim 3, comprising wherein a substrate temperature of the substrate during the deposition of the dielectric layer is between 150° C. and 500° C.

5. The method of claim 1, comprising:
depositing the dielectric layer using a vapor deposition method,
wherein the process atmosphere has the first starting component, the second starting component and the third starting component at the first point in time.

6. The method of claim 5, comprising wherein a substrate temperature of the substrate during the deposition of the dielectric layer is between 0° C. and 700° C.

7. The method of claim 1, comprising wherein a pressure of the process atmosphere is between 10-10 torr and 10 torr.

8. The method of claim 1, comprising feeding the third starting component to the process atmosphere in gaseous form.

9. The method of claim 8, comprising initially converting the third starting component from a solid or liquid state into a gaseous state.

10. The method of claim 9, comprising atomizing the halogen of the third starting component by a plasma.

11. The method of claim 9, comprising ionizing the halogen of the third starting component by a plasma.

12. The method of claim 1, comprising wherein the first starting component consists of at least one of hafnium, barium, strontium, titanium, silicon, zirconium, lead, tantalum and aluminum.

13. The method of claim 1, comprising enhancing the deposition of the dielectric layer by a plasma.

14. The method of claim 1, comprising activating the deposition of the dielectric layer by a plasma.

15. The method of claim 1, comprising wherein the process atmosphere has the first starting component at a fourth point in time, and wherein the third starting component is substantially absent in the process atmosphere at the fourth point in time, wherein the process atmosphere has the third starting component at a fifth point in time.

16. The method of claim 15, comprising wherein the process atmosphere has the third starting component in a first concentration at the third point in time and the process atmosphere has the third starting component in a second concentration at the fifth point in time.

17. The method of claim 16, comprising wherein the first concentration substantially corresponds to the second concentration.

18. The method of claim 1, wherein the process atmosphere comprises at least one further first starting component at least one further point in time.

19. The method of claim 1, wherein the method comprises densifying the dielectric layer.

20. A method for producing an integrated circuit, comprising:
providing a substrate; and
depositing a dielectric layer on the substrate in a process atmosphere,
wherein the process atmosphere comprises a first starting component, a second starting component and a third starting component,
wherein the third starting component comprises a halogen, and
wherein the dielectric layer comprises a high concentration of the third component at an interface with the substrate in order to enable unsaturated bonds to be saturated.

21. The method of claim 20, wherein the third starting component comprises at least one of the elements of the halogens fluorine, chlorine, bromine or iodine.

22. An integrated circuit comprising:
a substrate;
a dielectric layer on the substrate, wherein the dielectric layer has a volume region having an interface with the substrate,
wherein the volume region has a first component, a second component and a third component, and
wherein the third component comprises a halogen.

23. The integrated circuit of claim 22, wherein the third component comprises one of the halogens fluorine, chlorine, bromine and iodine.

24. The integrated circuit of claim 22, wherein the first component comprises at least one of hafnium, barium, strontium, titanium, silicon, zirconium, lead, tantalum and aluminum.

25. The integrated circuit of claim 22, wherein the second component comprises at least one of oxygen and nitrogen.

26. An integrated circuit comprising:
a dielectric layer on the substrate, the dielectric layer comprising:
a first component;
a second component; and
a third component,
wherein the third component comprises a halogen, and
wherein the dielectric layer comprises a high concentration of the third component at the interface with the substrate in order to enable unsaturated bonds to be saturated.

27. The integrated circuit of claim 26, wherein the third component comprises one of the halogens fluorine, chlorine, bromine and iodine.

28. The integrated circuit of claim 26, comprising wherein a concentration of the third component varies along a normal to the interface.

29. The integrated circuit of claim 26, comprising wherein the concentration has a maximum along the normal.

30. The integrated circuit of claim 26, comprising wherein the concentration has a minimum along the normal.

31. The integrated circuit of claim 26, comprising wherein the concentration has a substantially linear profile along the normal.

32. A semiconductor component comprising:
a first component;
a second component; and
a third component,
wherein the third component comprises a halogen, and
wherein the dielectric layer comprises a high concentration of the third component at the interface within the dielectric layer in order to enable unsaturated bonds to be saturated.

33. The semiconductor component of claim 32, wherein the third component comprises one of the halogens fluorine, chlorine, bromine and iodine.

34. The semiconductor component of claim 32, comprising wherein a concentration of the third component varies along a normal to the interface.

35. The semiconductor component of claim 32, comprising wherein the concentration has a maximum along the normal.

36. The semiconductor component of claim 32, comprising wherein the concentration has a minimum along the normal.

37. The semiconductor component of claim 32, comprising wherein the concentration has a substantially linear profile along the normal.
